(19) United States
(12) Patent Application Publication
(10) Pub. No.: US 2015/0162186 A1
(43) Pub. Date: Jun. 11, 2015

(54) Method for producing a layer of a compound semiconductor

(71) Applicant: Fraunhofer-Gesellschaft zur Förderung der angewandten Forschung e.V., Munchen (DE)

(72) Inventors: Klaus Köhler, Freiburg (DE); Stefan Müller, Gundelfingen (DE); Steffen Breuer, Freiburg (DE)

(21) Appl. No.: 14/566,146

(22) Filed: Dec. 10, 2014

(30) Foreign Application Priority Data
Dec. 11, 2013 (DE) 102013225632.9

(51) Int. Cl. H01L 21/02

(52) U.S. Cl. CPC H01L 21/0254; H01L 21/0262

(57) ABSTRACT

The invention relates to a method for producing a layer by means of MOVPE, wherein the layer comprises or consists of at least one III-V compound semiconductor and carbon, wherein the compound semiconductor comprises at least one element of main group III of the periodic table which is selected from any of gallium, aluminum, indium and/or boron, and wherein the compound semiconductor comprises at least nitrogen and wherein the compound semiconductor comprises optionally at least one further element of main group V which is selected from any of phosphorus and/or arsenic, wherein the method comprises the steps of: introducing a substrate into a vacuum chamber; evacuating the vacuum chamber to a background pressure; heating the substrate to a predefinable temperature; introducing at least one precursor gas into the vacuum chamber, said gas comprising or consisting of nitrogen; introducing at least one precursor comprising an organometallic compound into the vacuum chamber; introducing at least one hydrocarbon compound into the vacuum chamber.

### CROSS-REFERENCE TO RELATED APPLICATIONS

This application claims priority from German application No. 102013225632.9, filed Dec. 11, 2013 which is incorporated herein by reference in its entirety.

### BACKGROUND OF THE INVENTION

The invention relates to a method for producing a layer on a substrate, wherein the layer comprises or consists of at least one III-V compound semiconductor, wherein the compound semiconductor comprises at least one element of the third main group of the periodic table, said element being selected from any of gallium, aluminum, indium and/or boron, and the compound semiconductor also comprises at least nitrogen and optionally at least one further element of the fifth main group which is selected from any of phosphorus and/or arsenic. Layers of the above mentioned type may be used for the production of optoelectronic semiconductor devices or power semiconductors, for example.

It is known in the art to deposit said III-V compound semiconductors on a substrate. The substrate may comprise or consist of silicon or sapphire, for example. Since these substrates have another lattice constant than the III-V compound semiconductor constituting said layer, it is known to arrange a buffer layer between the semiconductor device and the substrate before producing the III-V compound semiconductor layer, so that said layer may have an enhanced crystal quality.

H. Tang, J. B. Webb, J. A. Bardwell and T. MacElwee: “Growth of high-performance GaN modulation-doped field-effect transistors by ammonia-molecular-beam epitaxy”, J. Vac. Sci. Technol. A 18(2), March/April 2000 652, disclose the use of a GaN layer as a buffer layer and doping the material of said buffer layer with carbon. As a result of the carbon doping, the electric resistance of the buffer layer increases so as to avoid short circuits or parasitic currents between different semiconductor devices being arranged on said buffer layer.

However, this known buffer layer has the drawback that the methane gas used as a carbon source must be dissociated in a gas discharge. As such a gas discharge may only be operated safely in an ultrahigh vacuum the use of this known method is limited to MBE deposition of compound semiconductors. Furthermore, the observed charge carrier mobility is poor. Therefore it has to be assumed that the quality of the buffer layers produced with this known method is insufficient.

Therefore, it is an object of the invention to provide a method for producing a layer of a carbon-doped III-V compound semiconductor having a better crystal quality.

### SUMMARY

In one aspect, the invention relates to a method for producing a layer by means of MOVPE, wherein the layer comprises or consists of at least one III-V compound semiconductor and carbon, wherein the compound semiconductor comprises at least one element of main group III of the periodic table which is selected from any of gallium, aluminum, indium and/or boron, and wherein the compound semiconductor comprises at least nitrogen and wherein the compound semiconductor comprises optionally at least one further element of main group V which is selected from any of phosphorus and/or arsenic, wherein the method comprises the steps of: introducing a substrate into a vacuum chamber; evacuating the vacuum chamber to a background pressure; heating the substrate to a predefinable temperature; introducing at least one precursor gas into the vacuum chamber, said gas comprising or consisting of nitrogen; introducing at least one precursor comprising an organometallic compound into the vacuum chamber; introducing at least one hydrocarbon compound into the vacuum chamber.

In one aspect, the invention relates to a method for producing a layer by means of MOVPE, wherein the layer comprises or consists of at least one III-V compound semiconductor and carbon, wherein the compound semiconductor comprises at least one element of main group III of the periodic table which is selected from any of gallium, aluminum, indium and/or boron, and wherein the compound semiconductor comprises at least nitrogen and wherein the compound semiconductor comprises optionally at least one further element of main group V which is selected from any of phosphorus and/or arsenic, wherein the method comprises the steps of: introducing a substrate into a vacuum chamber; evacuating the vacuum chamber to a background pressure; heating the substrate to a predefinable temperature; introducing at least one precursor gas into the vacuum chamber, said gas comprising or consisting of nitrogen; introducing at least one precursor comprising an organometallic compound into the vacuum chamber; introducing at least one hydrocarbon compound into the vacuum chamber, wherein the hydrocarbon comprises at least one alkane having 1 to 7 carbon atoms.

### BRIEF DESCRIPTION OF THE DRAWINGS

The invention shall be illustrated in more detail below by making reference to exemplary embodiments without limiting the general inventive concept. Some aspects of the invention may be understood with reference to the appended drawings, wherein

FIG. 1 illustrates the inventory of elements of different layers according to the invention.

FIG. 2 illustrates a process chart of the method according to the invention.

### DETAILED DESCRIPTION OF THE INVENTION

According to one aspect of the invention, at least one layer is deposited on a substrate. The layer may comprise or consist of a III-V compound semiconductor and carbon. The layer may be deposited by means of a process called metalorganic vapour phase epitaxy (MOVPE).

In the context of this description, MOVPE is understood to denote a process to deposit a layer from the gas phase in a rough vacuum, i.e. a pressure in the rage between approximately 300 hPa and approximately 10-3 hPa or a pressure in the rage between approximately 500 hPa and approximately 20 hPa. Since the elements of the third main group of the periodic system are metals, they maynot be introduced to the gas phase in an elemental form at typical growth temperatures. Therefore, organometallic compounds and/or metal hydrides are used as precursors for the epitaxy process. These compounds have a sufficiently low vapor pressure and may therefore be evaporated into the gas phase easily. Once the organometallic compounds are evaporated, they may be transported through pipes from the source to the target. Thus, the organometallic compounds may be provided in closed containers which are kept at a constant temperature by means of a heating device and a controller. This leads to a constant vapor pressure above the solid or liquid phase and serves for easily keeping constant the mass flow of the respective compound in the vacuum chamber or the reaction vessel.

In some embodiments of the invention, an optional carrier gas may be used to promote the diffusion of the organometallic compounds into the vacuum chamber.

The substrate being intended for the layer deposition is heated to an elevated temperature by any of resistance heating and/or infrared radiation and/or induction heating. As a result, the organometallic compounds and/or metal hydrides dissociate on the substrate surface. Volatile components, e.g. hydrocarbons and/or hydrogen, are subsequently converted into the gas phase again and removed by at least one vacuum pump, whereas the metal atoms are deposited on the substrate.

In some embodiments of the invention, the III-V compound semiconductor which constitutes the material of the at least one layer comprises at least one element of the third main group which is selected from any of gallium, aluminum, indium and/or boron. The compound semiconductor also comprises at least nitrogen. In some embodiments of the invention, the compound semiconductor may additionally comprise any of phosphorus and/or arsenic. The compound semiconductor thus comprises a binary, ternary or quaternary compound from elements of main groups III and V of the periodic system. For example, the compound semiconductor may be selected from GaN, AlGaN, AlInN, AlGaNP or similar compounds which are not mentioned explicitly herein.

In some embodiments of the invention, the method according to the invention may be used to deposit a plurality of layers having different composition on the substrate. In some embodiments, the substrate may initially be provided with a buffer layer being intended to reduce the lattice mismatch of subsequent layers. Semiconductor structures may be deposited on the buffer layer, e.g. to produce an optoelectronic component or a transistor. Said components may comprise quantum well structures or other semiconductor heterostructures, being adapted to form a two-dimensional electron gas. In some embodiments of the invention, the electron mobility in such a two-dimensional electron gas may be greater than 1100 cm2/Vs or greater than 1300 cm2/Vs.

According to the invention, the electric resistance of at least the buffer layer made of the III-V compound semiconductor may be increased by doping the material of said buffer layer with carbon. In some embodiments, at least one hydrocarbon may be introduced into the vacuum chamber. According to the invention, it has been realized that the hydrocarbon is dissociated on the substrate surface in the same way as described above for organometallic compounds. As a result, the carbon may be incorporated into the deposited layer in such a way that it is electrically active. Excess carbon or non-dissociated hydrocarbons may be desorbed from the substrate surface to the gas phase again and subsequently be removed from the inner volume of the vacuum chamber by a respective vacuum pump. In contrast to known manufacturing methods, no gas discharge has to be used for the dissociation of the hydrocarbons.

It has turned out that the introduction of hydrocarbons into the vacuum chamber during a MOVPE process may be suitable to provide layers having high crystal quality and high carbon doping. Hydrocarbons as a precursor material of layer deposition are not toxic and widely spread, and therefore it is easy to procure these substances and safe and easy to use them. On account of its high layer quality, the resulting layer is suitable to produce high quality components having few crystal defects. Due to the large amount of electrically active carbon in the layer, appropriately high electric resistances may be achieved so as to avoid the occurrence of short circuits or other parasitic currents flowing between different semiconductor devices on the same substrate and/or the same buffer layer.

In some embodiments of the invention, the hydrocarbon may comprise or consist of an alkane. Alkanes have the advantage that they do not comprise a double bond, as a result of which the molecules may readily dissociate on the substrate surface due to the low bonding energy. Therefore, doping with carbon may already be effected at low substrate temperatures.

In some embodiments of the invention, the hydrocarbon may comprise or consist of an alkane having 1 to 7 carbon atoms. These light alkanes may be provided with a high degree of purity so as to limit unavoidable contaminations of the resulting layer by undesired impurity atoms.

In some embodiments of the invention, the hydrocarbon may comprise methane. Methane has the advantage that it may be provided with a high degree of purity and dissociates at temperatures below 1000° C., and therefore the integration into the layer may be possible even at low growth temperatures and/or low substrate temperatures. Furthermore, methane dissociates into one carbon atom and two hydrogen molecules which, due to their low mass, have a high diffusion rate and therefore may be rapidly removed from the vacuum chamber.

In some embodiments of the invention, the hydrocarbon may comprise or consist of pentane. Pentane has a boiling point of 36° C. at normal pressure and may therefore be supplied in the same way as the known organometallic compounds used for layer deposition. For this purpose, pentane may be provided in a closed container which is kept at a constant temperature by means of a heating device and a controller so as to adjust a constant vapor pressure. The vapor may then be introduced into the vacuum chamber via a mass flow controller. Thus, a carbon source using pentane as a raw material may be easily integrated in generally known and widespread MOVPE systems without any further adaptation of the MBE system. Only one container out of a plurality of containers must be filled with pentane to carry out the method according to the invention and deposit the carbon doped III-V compound semiconductors on the substrate.

In some embodiments of the invention, the substrate is heated to a temperature of about 900° C. to about 1200° C. In some embodiments of the invention, the substrate is heated to a temperature of about 1050° C. to about 1150° C. At this temperature, a plurality of hydrocarbons, in particular alkanes, decomposes to a substantial extent. Thus, a sufficient amount of carbon may be provided in a simply way to achieve the desired doping of the III-V compound semiconductor constituting the buffer layer. It is noteworthy that a plurality of III-V compound semiconductors may be produced at said temperature range, e.g. GaN or AlGaN.

In some embodiments of the invention, the substrate may be heated to a temperature of about 1080° C. to 1120° C. In this temperature range, the carbon doping may be influenced within wide limits, whereas a qualitatively high-grade layer may be deposited from the III-V compound semiconductor on the substrate.

In some embodiments of the invention, the gas comprising nitrogen may be selected from N2 and/or NH3. Ammonia is characterized as a hydride by its small bonding energies, and therefore it is possible to provide a sufficient amount of atomic nitrogen with low substrate temperatures.

In some embodiments of the invention, the organometallic compound may comprise Ga and/or Al and/or In. As a result, the metallic component of the III-V compound semiconductor may be provided at a low temperature. In some embodiments of the invention, the organometallic compound may comprise or consist of Ga(CH3)3.

In some embodiments of the invention, the background pressure may be less than 1 hPa or less than 1.10-2 hPa. As a result, the occurrence of impurities from the residual gas is minimized and qualitatively high-grade semiconductor layers may be deposited on the substrate.

In some embodiments of the invention, the pressure may raise to a value of about 25 hPa to about 220 hPa or about 30 hPa to about 100 hPa at the time when the at least one organometallic compound, the nitrogen comprising gas, and the hydrocarbon are introduced. In this pressure range, the medium free path length is great enough to ensure a sufficiently high collision rate with the substrate, thereby resulting in a sufficiently high growth rate of the layer. On the other hand, the growth rate is slow enough to produce high quality layers, in particular monocrystalline or nearly monocrystalline layers by epitaxial growth.

In some embodiments of the invention, the hydrocarbon may be supplied in an amount of about 9 millimoles per minute (mmol/min) to 47 millimoles per minute (mmol/min). In this range, the dopant concentration may be adjusted in such a way that little electrically inactive carbon, which would negatively affect the layer quality, is present in the layer. On the other hand, the incorporation of carbon is high enough to allow for the desired low conductivity of the layers.

In some embodiments of the invention, the number of carbon atoms in the layer may be between approximately 1.1018 cm−3 and approximately 2.1020 cm−3.

In some embodiments of the invention, the layer may have a leakage current of less than 1 μA at an electric voltage of 1000 V. In some embodiments of the invention, the layer may have a leakage current of less than 1 nA at an electric voltage of 400 V.

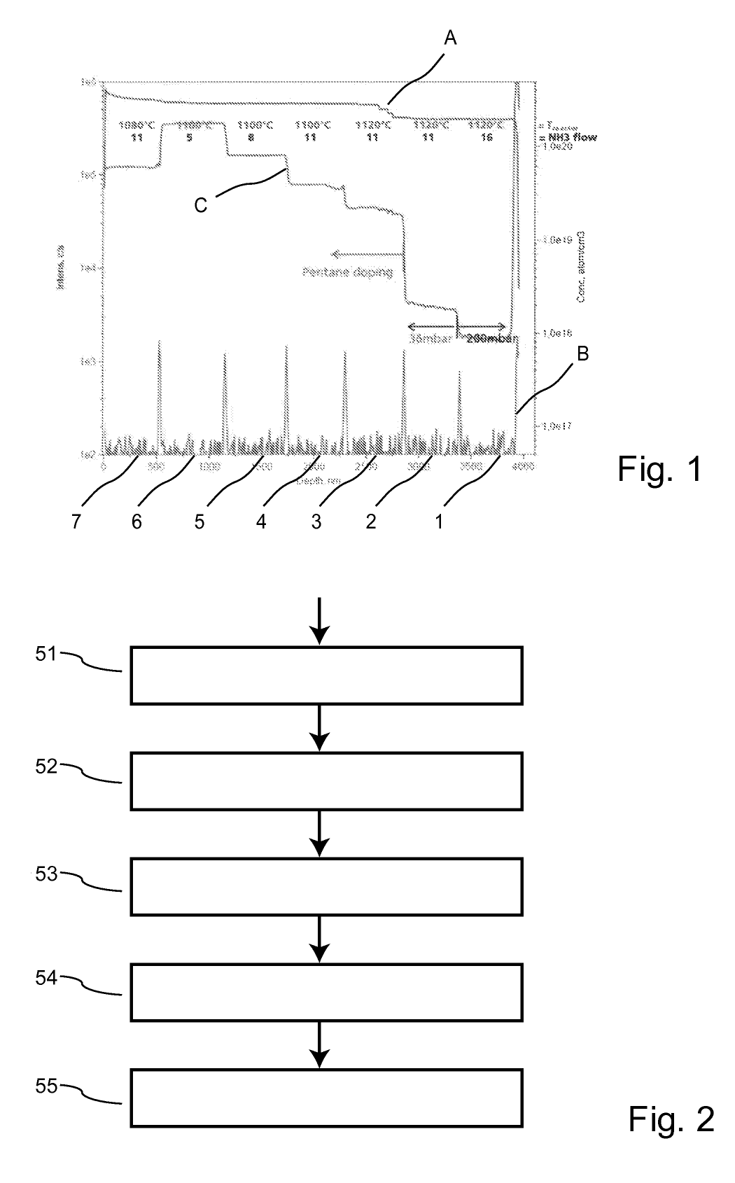

Turning now to the appended drawings, FIG. 1 illustrates by way of example the influence of different parameters on the composition of the layers according to the invention. For this purpose, different layers each having a thickness of about 500 nm were produced directly on top of one another on a single substrate and then the depth profile of different elements was determined.

The layers were produced on a substrate which substantially consists of sapphire. In addition, the substrate may comprise dopants and/or unavoidable impurities.

The substrate was introduced on a heatable substrate holder into a vacuum chamber which was then evacuated up to a background pressure. The first layer was deposited directly on the substrate. For this purpose, ammonia was introduced into the vacuum chamber with a mass flow of 16 standard liters per minute (slm). One slm corresponds to 16.8875 mbar.1.s-1. Additionally, trimethylgallium was introduced such that a resulting total pressure of 200 millibars was obtained. By heating the substrate to 1120° C., the gas phase in the vacuum chamber is activated to such an extent that the trimethylgallium and the ammonia dissociate and a GaN layer is deposited on the substrate.

In the next method step, the ammonia flow was reduced to 11 slm, such that a total pressure of 36 hPa was obtained. A second layer having a thickness of about 500 nanometers was deposited on the initially produced first layer under these conditions. The third layer was deposited directly on the second layer. In order to deposit the third layer, a flow of 9 mmol/min pentane was additionally introduced into the vacuum chamber. The fourth layer was deposited directly on the third layer. For this purpose, the temperature was lowered by 20° C. to then 1100° C. The fifth layer was deposited directly on the fourth layer. In order to deposit the fourth layer, the ammonia flow was lowered to 8 slm, whereas pentane and trimethylgallium were added without any change. The sixth layer was deposited directly on the fifth layer. In order to deposit the sixth layer, the ammonia flow was further lowered to then 5 slm. In order to deposit the seventh layer, the ammonia flow was again increased to 11 slm and the temperature was lowered by 20° C. to then 1080° C. In order to be able to distinguish the seven individual layers in the depth profile, the layer boundaries were all provided with a silicon doping.

FIG. 1 illustartes the depth in nanometers on the abscissa and the concentration in atoms per cm3 on the ordinate. In this connection, curve A is the gallium concentration, curve C is the carbon concentration and curve B is the silicon concentration. The elemental inventory according to FIG. 1 was determined by means of secondary ion mass spectrometry (SIMS). The measurement was made by bombarding the material sample with primary ions having an energy of 0.2 to 25 keV. The resulting positively or negatively charged ions are identified by means of mass filters. The signal intensity as a measure of the particle amount serves for the assessment of the composition.

The finally deposited seventh layer is at the lowest depth and extends from the surface down to about 500 nanometers. This layer is followed by the sixth layer as the penultimate layer, up to the first layer, which is directly arranged on the substrate surface at the greatest possible depth.

Curve B shows the concentration of silicon atoms. Since doping was carried out at each of the layer boundaries, the seven individual layers are clearly identified in curve B. For a better understanding, the individual layers are marked with reference signs 1 to 7.

Curve C shows the carbon content. The first layer was deposited at a total pressure of 200 millibars without the supply of hydrocarbons. Since trimethylgallium also comprises carbon and this compound is dissociated on the substrate surface, the nominally undoped layer also comprises approximately 1.1018 carbon atoms per cm3. As shown by the second layer, the carbon content increases slightly by a factor of about 2 when the supply of ammonia is reduced and the total pressure drops to 36 millibars.

The influence of pentane manifests itself in the third layer. The latter comprises approximately 1.1019 carbon atoms per cm3, i.e. a factor of 10 more compared to the nominal undoped second layer.

As shown in the fourth layer, the doping with carbon may be increased by a reduction in the substrate temperature during the layer growth. In this respect, FIG. 1 illustrates that the substrate temperature may be used as an additional parameter for the control of the carbon content in addition to the supply of pentane and/or other hydrocarbons.

Layers 5 and 6 illustrate that the carbon content continues to increase when the supply of ammonia is reduced even though the substrate temperature and the supply of trimethylgallium and pentane remain unchanged.

A comparison between the seventh, third and fourth layers reveals the influence of the substrate temperature with equal composition of the gas atmosphere. It has been shown that doping increases with decreasing temperature.

Layer 4 compared to Layer 2 illustrates that the carbon content may be adjusted by more than two orders of magnitude from about 1.1818 to 1.1020 atoms per cm3.

Curve A of FIG. 1 shows the gallium content. The increase shown in FIG. 1 is based on a static charge of the material sample during SIMS analysis. This static charge is due to the low conductivity of the layers produced according to the method disclosed by the invention. Thus, curve A also shows that the carbon is inserted in the crystal lattice to a noteworthy extent on electrically active lattice sites or interstitial sites. In the layers produced according to the invention, leakage currents below 1 μA were measured at 1000 Volt and less than 1 nA at 400 Volt.

FIG. 2 illustrates a flow diagram of an embodiment of the method according to the invention.

In the first method step 51, a substrate is introduced into a vacuum chamber. For example, the substrate may comprise or consist of sapphire or silicon. In addition, the substrate may comprise dopants to adjust a predefinable electric conductivity.

In the second method 52, the vacuum chamber is evacuated to a predefinable background pressure. The background pressure may be less than 1 hPa in some embodiments of the invention. As a result, less impurities may be added from the residual gas to the subsequently deposited layer. After the evacuation of the vacuum chamber, an optional cleaning step of the substrate may follow.

In the third method step 53, the substrate is heated to a predefinable temperature. In some embodiments of the invention, induction heating may be used. However, other heating means may be used instead, e.g. resistance heating or radiant heating. The target temperature may be chosen to be between about 900° C. and about 1200° C. in some embodiments. The temperature may be modified during the growth of different layers to influence the composition of the respectively forming layer.

In the fourth method step 54, the precursors of the layer to be deposited are introduced into the vacuum chamber. For example, at least one organometallic compound and at least one nitrogen-comprising gas may be introduced into the vacuum chamber. In some embodiments, an optional carrier gas may be used as well. In some embodiments, the carrier gas may comprise H2. The total pressure in the vacuum chamber is given by the mass flows of the precursors and the throughput of the vacuum pumps used. The relative composition of the layer may be adjusted by the respective mass flows of the introduced precursors and the substrate temperature. The at least one organometallic compound and the at least one nitrogen-comprising gas may be introduced at the same time or one after the other in different order.

Finally, carbon doping is carried out in the fifth method step 55 by introducing at least one hydrocarbon compound. In some embodiments of the invention, an alkane having one to seven carbon atoms may be used. In some embodiments of the invention, methane and/or pentane may be used.

By heating the substrate to a predefinable temperature, the precursors introduced into the preceding method steps are dissociated, and thus, a carbon-doped layer of a III-V compound semiconductor is deposited on the substrate. If the temperature and the mass flows of the precursors are controlled within the correct ranges, this layer may be deposited on the substrate as a monocrystalline or almost monocrystalline layer with a very low defect density.

By subsequent modification of the mass flows of organometallic compounds, hydrocarbon compounds and nitrogen-comprising gases, it is possible to deposit different layers on top of one another, said layers differing e.g. as regards the composition and/or doping, and therefore semiconductor heterostructures may also be deposited on the insulating layer manufactured according to the invention. In some method steps, additional compounds may be introduced or the supply of hydrocarbon compounds may be dispensed with.

The invention is, of course, not limited to the embodiments shown in the figures. Therefore, the above description should not be regarded as limiting but explanatory. In particular, the order of the method steps shown in FIG. 2 may also be modified. The following claims should be understood in such a way that a feature mentioned is present in at least one embodiment of the invention. This does not rule out the presence of further features. If the claims and the above description define “first” and “second” features, this designation serves for distinguishing between two similar features without determining a ranking.

1. Method for producing a layer by means of MOVPE, wherein the layer comprises or consists of at least one III-V compound semiconductor and carbon, wherein the compound semiconductor comprises at least one element of main group III of the periodic table which is selected from any of gallium, aluminum, and/or indium, and
wherein the compound semiconductor comprises at least nitrogen and
wherein the compound semiconductor comprises optionally at least one further element of main group V which is selected from any of phosphorus and/or arsenic,
wherein the method comprises the steps of:
introducing a substrate into a vacuum chamber;
evacuating the vacuum chamber to a background pressure;
heating the substrate to a predefinable temperature;
introducing at least one precursor gas into the vacuum chamber, said gas comprising or consisting of nitrogen;
introducing at least one precursor comprising an organometallic compound into the vacuum chamber;
introducing at least one hydrocarbon compound into the vacuum chamber.

2. Method according to claim 1, wherein the hydrocarbon comprises or consists of an alkane.

3. Method according to claim 2, wherein the hydrocarbon comprises or consists of an alkane having 1 to 7 carbon atoms

4. Method according to claim 2, wherein the hydrocarbon comprises any of methane and/or pentane.

5. Method according to claim 1, wherein the substrate is heated to a temperature being selected from the range between 1050° C. to 1180° or between 900° C. to 1200° C.

6. Method according to claim 1, wherein the nitrogen containing gas is selected from any of N₂ and/or NH₃.

7. Method according to claim 1, wherein the organometallic compound comprises Ga and/or Al and/or In.

8. Method according to claim 1, wherein the hydrocarbon is supplied in an amount of about 9 mmol/min to about 47 mmol/min.

9. Method according to claim 1, wherein the background pressure is less than 1 hPa.

10. Method according to claim 1, wherein the pressure increases to a value of about 25 hPa to about 220 hPa or about 30 hPa to about 100 hPa when the organometallic compound and the nitrogen comprising gas and the hydrocarbon are introduced.

11. Method according to claim 1, wherein the number of carbon atoms in the layer is selected between 1·10¹⁸ cm⁻³ and 2·10²⁰ cm⁻³.

12. Method according to claim 1, wherein the layer obtained has a leakage current of less than 1 μA at an electric field applied from 2 V/nm and/or that the layer has a leakage current of less than 1 nA at an electric field applied of 0.8 V/nm.

13. Method according to claim 1, wherein the layer comprises or consists of GaN and/or AlGaN and/or AlInN.

14. Method for producing a layer by means of MOVPE, wherein the layer comprises or consists of at least one III-V compound semiconductor and carbon, wherein the compound semiconductor comprises at least one element of main group III of the periodic table which is selected from any of gallium, aluminum, indium and/or boron, and
wherein the compound semiconductor comprises at least nitrogen and
wherein the compound semiconductor comprises optionally at least one further element of main group V which is selected from any of phosphorus and/or arsenic,
wherein the method comprises the steps of:
introducing a substrate into a vacuum chamber;
evacuating the vacuum chamber to a background pressure;
heating the substrate to a predefinable temperature;
introducing at least one precursor gas into the vacuum chamber, said gas comprising or consisting of nitrogen;
introducing at least one precursor comprising an organometallic compound into the vacuum chamber;
introducing at least one hydrocarbon compound into the vacuum chamber, wherein the hydrocarbon comprises at least one alkane having 1 to 7 carbon atoms.

15. Method according to claim 14, wherein the hydrocarbon comprises any of methane and/or pentane.

16. Method according to claim 14, wherein the substrate is heated to a temperature being selected from the range between 1050° C. to 1180° or between 900° C. to 1200° C.

17. Method according to claim 14, wherein the nitrogen containing gas is selected from any of N₂ and/or NH₃.

18. Method according to claim 14, wherein the organometallic compound comprises Ga and/or Al and/or In.

19. Method according to claim 14, wherein the hydrocarbon is supplied in an amount of about 9 mmol/min to about 47 mmol/min.

20. Method according to claim 14, wherein the number of carbon atoms in the layer is selected between 1·10¹⁸ cm⁻³ and 2·10²⁰ cm⁻³.
